(19) United States
(12) Patent Application Publication
(10) Pub. No.: US 2025/0054796 A1
(43) Pub. Date: Feb. 13, 2025

(54) INTEGRATED LOAD PORT FIRST AID PLATFORM

(71) Applicant: Taiwan Semiconductor Manufacturing Company, Ltd., Hsinchu (TW)

(72) Inventors: Chia-Hsi Wang, Changhua County (TW); ChunKai Yu, Hsinchu (TW); Yi-Ming Chen, Taipei (TW); Yen-Yu Chen, Taichung (TW); Yi-Fu Chen, Miaoli County (TW)

(21) Appl. No.: 18/230,662

(22) Filed: Aug. 7, 2023

(51) Int. Cl. H01L 21/677; G05B 19/418

(52) U.S. Cl. CPC H01L 21/67775; G05B 19/4184; H01L 21/67742; G05B 2219/45031

(57) ABSTRACT

A system is provided. The system includes: a semiconductor processing system comprising: a semiconductor processing apparatus configured to perform at least one semiconductor fabrication process; and a load port attached to the semiconductor processing apparatus and configured to load a wafer contained in a wafer container to the semiconductor processing apparatus; and a load port first aid platform in electrical communication with the load port, wherein the load port first aid platform controls the load port when the semiconductor processing apparatus malfunctions.

### FIELD

Embodiments of the present disclosure relate generally to semiconductor processing, and more particularly to integrated load port first aid platforms.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area.

While some integrated device manufacturers (IDMs) design and manufacture integrated circuits (IC) themselves, fabless semiconductor companies outsource semiconductor fabrication to semiconductor fabrication plants or foundries. Semiconductor fabrication consists of a series of processes in which a device structure is manufactured by applying a series of layers onto a substrate. This involves the deposition and removal of various dielectric, semiconductor, and metal layers. The areas of the layer that are to be deposited or removed are controlled through photolithography. Each deposition and removal process is generally followed by cleaning as well as inspection steps. Therefore, both IDMs and foundries rely on numerous semiconductor equipment and semiconductor fabrication materials, often provided by vendors. There is always a need for customizing or improving those semiconductor equipment and semiconductor fabrication materials, which results in more flexibility, reliability, and cost-effectiveness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating an example load port first aid platform in conjunction with a semiconductor processing system 100 in accordance with some embodiments.

FIG. 2 is a diagram illustrating an example load port first aid platform in conjunction with a semiconductor processing system 100 in accordance with some embodiments.

FIG. 3 is a block diagram illustrating an example load port first aid control system in accordance with some embodiments.

FIG. 4 is a diagram illustrating an example load port first aid terminal in accordance with some embodiments.

FIG. 5 is a flowchart diagram illustrating an example method for operating a load port first aid platform in accordance with some embodiments.

FIG. 6 is a diagram illustrating an example load port in conjunction with an example load port first aid terminal in accordance with some embodiments.

FIG. 7 is a diagram illustrating an environment in which an example load port operates in accordance with some embodiments.

FIG. 8 is a block diagram illustrating an example load port first aid platform in conjunction with a first semiconductor processing system and a second semiconductor processing system in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

### Overview

During manufacturing of a semiconductor device, the device is usually processed at many work stations or processing machines. The transporting or conveying of a partially finished semiconductor wafer, or a work-in-process (WIP) part, is an important aspect in the total fabrication process. The conveying of semiconductor wafers is especially important in the fabrication of integrated circuit (IC) chips due to the delicate nature of the chips. Furthermore, in fabricating an IC product, a multiplicity of fabrication steps, i.e., as many as several hundred, is usually required to complete the fabrication process. A semiconductor wafer or IC chips must be stored or transported among various process stations in order to go through various fabrication processes.

Automated Material Handling Systems (AMHS) have been widely used in semiconductor fabrication facilities (“FABs”) to automatically handle and transport groups or lots of wafers among various semiconductor processing systems used in chip fabrication. Multiple wafers are typically stored and transported together in wafer containers by the AMHS between load ports of different semiconductor processing systems during the semiconductor fabrication process. The load port is used to handle semiconductor wafers to be processed.

The AMHS in a semiconductor FAB includes numerous types of automated and manual vehicles for moving and transporting the wafer containers throughout the FAB during the fabrication process. This can include for example automatic guided vehicles (AGVs), personal guided vehicles (PGVs), rail guided vehicles (RGVs), overhead shuttles (OHSs), and overhead hoist transports (OHTs). Of the foregoing AMHS wafer transport mechanisms, OHTs are commonly used to transport wafer containers, from the load port of one semiconductor processing system to the load port of the next semiconductor processing system in the processing sequence. A wafer container transported by an OHT transfer system typically has a door. During the transfer process, for production quality control, the door is used to seal the wafer container against entry of external contaminants to keep wafers inside the wafer container clean, and/or to protect the wafers from falling off the wafer container.

A load port may be affiliated with its corresponding semiconductor processing system. As a result, operations of the load port are typically controlled by a control system of the semiconductor processing system, or a control system shared by multiple semiconductor processing systems. In other words, the control over the load port is centralized.

When an anomaly occurs in the semiconductor processing system, the control system stops the semiconductor processing system. However, since the control over the load port is centralized, the control system stops the load port simultaneously. The functions of the load port can be recovered by the control system when the anomaly disappears, and the semiconductor processing system recovers. However, this recovery process can take a long time, and the load port and a wafer container may be exposed to atmosphere in the FAB for such a long period of time.

Alternatively, a technician can step in and manually recover the load port. Specifically, the technician can manually close the door of the load port, or manually close the door of a water carrier. In one example, the technician manually operates electrical solenoid valves, which are separated from and independent of the control system, to perform some functions of the load port (e.g., closing the door of the load port, closing the door of a wafer container). However, load ports provided by different vendors have different specifications and communication protocols, and manually operating the electrical solenoid valves is a complicated and skillful operation. This increases the risk of mishandling by the technician.

In accordance with some aspects of the disclosure, a system is provided. The system includes a semiconductor processing system and a load port first aid platform. The semiconductor processing system includes: a semiconductor processing apparatus configured to perform at least one semiconductor fabrication process; and a load port attached to the semiconductor processing apparatus and configured to load a wafer contained in a wafer container to the semiconductor processing apparatus. The load port first aid platform is in electrical communication with the load port and controls the load port when the semiconductor processing apparatus malfunctions.

### Example Load Port First Aid Platform

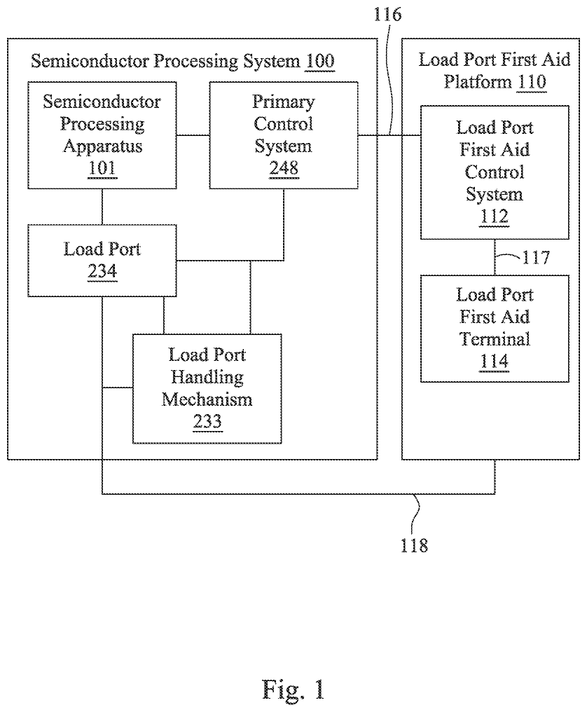

FIG. 1 is a block diagram illustrating an example load port first aid platform 110 in conjunction with a semiconductor processing system 100 in accordance with some embodiments. In the example shown in FIG. 1, a semiconductor processing system 100 includes, among other components, a semiconductor processing apparatus 101, a load port 234, a primary control system 248, and a load port handling mechanism 233. In the example shown in FIG. 1, the load port first aid platform 110 includes, among other components, a load port first aid control system 112 and a load port first aid terminal 114. Although a semiconductor processing system 100 is used as an example throughout the disclosure, it should be understood that the techniques discussed herein are generally applicable to other semiconductor fabrication systems such as a semiconductor metrology system (e.g., a system that measures the line width or hole diameter of a circuit pattern at a specified location, a system that measures the thickness of a thin film on the surface of a semiconductor wafer, a system that measures the accuracy of the overlay, etc.), a semiconductor testing system, a semiconductor packaging system (e.g., a pick-and-place system, a system that performs wafer-level packaging, etc.), and the like.

The semiconductor processing apparatus 101 is configured to perform at least one semiconductor fabrication process. A non-exhaustive list of processing techniques is as follows: wet cleans, surface passivation, photolithography (including photoresist coating, photoresist baking, exposure, and development), ion implantation, etching (including dry etching and wet etching), chemical vapor deposition (CVD), atomic layer deposition (ALD), physical vapor deposition (PVD), molecular beam epitaxy (MBE), plasma ashing, thermal treatments, laser lift-off, electrochemical deposition (ECD), chemical-mechanical polishing (CMP), wafer testing, through-silicon via (TSV) fabrication, wafer mounting, wafer back-grinding, wafer bonding, redistribution layer (RDL) fabrication, wafer bumping, die singulation, die attachment, die bonding, die encapsulation, IC testing, and the like. The semiconductor processing apparatus 101 is designed for one or more technology nodes, such as the 22 nm node, the 14 nm node, the 10 nm node, the 7 nm node, the 5 nm node, the 3 nm node, the 2 nm node, or even more advanced tech nodes.

The primary control system 248 is in electrical communication with the semiconductor processing apparatus 101 and controls the operations of the semiconductor processing apparatus 101. The primary control system 248 is also in electrical communication with the load port 234 and the load port handling mechanism 233 and controls the operations thereof.

The load port 234 is attached to the semiconductor processing apparatus 101 and serves as an interface between a wafer container and the semiconductor processing apparatus 101. Details of the load port 234 will be discussed below.

The load port handling mechanism 233 is configured to perform certain operations when an anomaly occurs in the semiconductor processing system 100 (e.g., when the semiconductor processing apparatus 101 malfunctions) and the primary control system stops or shuts down the semiconductor processing system 100, including the load port 234. For example, the load port handling mechanism 233 can open the door of a wafer container. As another example, the load port handling mechanism 233 can close the door of the load port 234. In one example, the load port handling mechanism 233 includes multiple electrical solenoid valves. It should be understood that other suitable load port handling mechanism 233 is within the scope of this disclosure. In some embodiments, the load port handling mechanism 233 is a stand-alone component. In other embodiments, the load port handling mechanism 233 is integrated into the load port 234.

Unlike in a typical system, the control over the load port 234 is decentralized, not centralized. At least a portion of the operations or functions of the load port 234 is controlled by the load port first aid platform 110 instead of the primary control system 248. In one embodiment, operations that are related to the troubleshooting (e.g., when an anomaly occurs and the load port 234 is stopped or shut down by the primary control system 248) of the load port 234 are controlled by the load port first aid platform 110, and other operations (e.g., the normal operations when there is no anomaly) are controlled by the primary control system 248. In one example, the load port first aid platform 110 controls the load port 234 to close a door of a wafer container. In another example, the load port first aid platform 110 controls the load port 234 to close the load port 234.

As such, the control over the troubleshooting operations of the load port 234 is independent of the primary control system 248. Without waiting for the semiconductor processing system 100 to recover, a technician can troubleshoot the load port 234 using the load port first aid platform 110, instead of through manual operation of electrical solenoid valves. Accordingly, the troubleshooting of the load port 234 becomes more secure and efficient.

The load port first aid platform 110 is in electrical communication with the load port 234 and the load port handling mechanism 233 through a communication path 118. As such, the load port first aid platform 110 can control the load port 234 and the load port handling mechanism 233 directly, bypassing the primary control system 248 of the semiconductor processing system 100 when an anomaly occurs.

On the other hand, the load port first aid control system 112 is in electrical communication with the primary control system 248 through a communication path 116. The load port first aid control system 112 is configured to troubleshoot the load port 234. Although the functioning of the load port first aid control system 112 is not dependent on the primary control system 248, the communication path 116 can serve some functions. For example, when the semiconductor processing system 100 recovers, the load port first aid control system 112 can transmit operational parameters of the load port 234 during the shutdown period to the primary control system 248 to facilitate the restart of the load port 234.

The load port first aid terminal 114 is in electrical communication with the load port first aid control system 112 through a communication path 117. The load port first aid terminal 114 is configured to provide a user interface between a technician and the load port first aid control system 112. Although the load port first aid terminal 114 is within the block of the load port first aid platform 110 and seems to be not in close proximity to the load port 234, as schematically shown in FIG. 1, it should be understood that the load port first aid terminal 114 is in close proximity to the load port 234 in some embodiments. Details of the load port first aid control system 112 and the load port first aid terminal 114 will be discussed below.

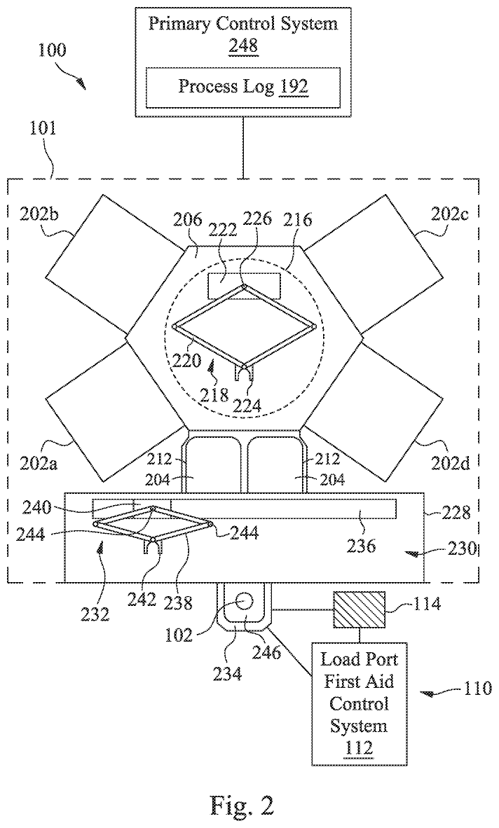

FIG. 2 is a diagram illustrating an example load port first aid platform 110 in conjunction with a semiconductor processing system 100 in accordance with some embodiments. The semiconductor processing system 100 shown in FIG. 2 is a multi-chamber semiconductor processing system, which is configured to process a wafer 102 or a batch of wafers 102 according to a process log 192 stored in, for example, the primary control system 248. In one example, a batch of wafers 102 are processed together, and the batch can include one hundred or more wafers 102. In another example, the semiconductor processing system 100 is configured to process a single wafer 102 at a time.

The semiconductor processing system 100 includes, among other things, a main frame 206, one or more load locks 204, multiple chambers 202a, 202b, 202c, and 202d (collectively, 202), a load port 234, wafer containers 246, a loading house 228, a primary control system 248. The main frame 206 is located at the center, and the one or more load locks 204 and the multiple chambers 202 are laterally spaced around and abutting the main frame 206. It should be understood that although two load locks 204 and four chambers 202 are illustrated in FIG. 2, this is not intended to be limiting. In other examples, other numbers (e.g., one, three, etc.) of load locks and other numbers (e.g., five, six, eight, ten, etc.) of chambers may be employed.

The load port 234 is configured to load wafers 102 contained in wafer containers (sometimes referred to as “pods”) 246 to the semiconductor processing apparatus 101. The wafer containers 246 can each accommodate a batch of wafers 102. In one embodiment, the wafer containers 246 are standard mechanical interface (SMIF) pods. In another embodiment, the wafer containers are front opening unified pods (FOUPs). Wafer containers 246 and the wafers 102 therein can be transported among various semiconductor processing systems in the FAB.

The loading housing 228 is located between the load port 234 and the load locks 204. In the example shown in FIG. 2, the loading housing 228 abuts the load locks 204 at one side, and the load port 234 is arranged on an opposite side of the loading housing 228 as the load locks 204.

The loading housing 228 defines a loading area 230 accommodating a loading robot 232 configured to transfer wafers 102 between the load port 234 and the load locks 204. In the example shown in FIG. 2, the loading robot 232 is arranged on a track 236 to move within the loading area 230. The loading robot 232 includes, in the example shown in FIG. 2, one or more rods 238 connected end to end between a motor 240 and a holding member 242 by one or more bearings 244. The motor 240 is configured to vertically, horizontally, and/or rotationally move the holding member 242 along the bearings 244. In one embodiment, the holding member 242 includes one or more blades, and each of the one or more blades includes a pair of laterally spaced fingers typically configured to support a single wafer 102. In one example, the holding member 242 includes five blades. In another embodiment, the holding member 242 includes one or more holding plates. It should be understood that the above embodiments or examples are not intended to be limiting, and the loading robot 232 may have various forms and designs.

Each of the load locks 204 is arranged in a load lock housing 212, abutting and mounted to a facet of the main frame 206. Each of the load locks 204 includes a corresponding load lock chamber configured to pass wafers 102 between environments on opposing sides of the load locks 204, while maintaining isolation between the environments. In some embodiments, the load lock chambers are individually sized to accommodate the same number of substrates as the chambers 202a-202d.

The main frame 206 includes a transfer chamber 216 central to the chambers 202a-202d and the load locks 204. The transfer chamber 216 accommodates a transfer robot 218 configured to transfer the wafer 102 among the chambers 202a-202d and the load locks 204, so as to facilitate loading and unloading of the wafer 102. During loading of the wafer 102, the wafer 102 is transferred from the load locks 204 to one or more of the chambers 202a-202d in a predetermined order according to the process log 192. Further, during unloading of the wafer 102, the wafer 102 is transferred from one of the chambers 202a-202d to the load locks 204. Although not shown in FIG. 2, the main frame 206 has openings that are aligned with corresponding sleeve doors located at the chambers 202a-202d and the load locks 204 to allow the transfer robot 218 to access the chambers 202a-202d during loading and unloading of the wafer 102. When loading and unloading are complete, the corresponding sleeve door closes and seals the corresponding opening. It should be understood that although the transfer of one wafer 102 is described above as an example, the transfer robot 218 is capable of transferring a batch of wafers 102 in other embodiments.

The chambers 202a-202d can be various chambers corresponding to various semiconductor processing equipment. In one example, the chamber 202a is a degassing chamber, the chamber 202b is a physical vapor deposition (PVD) chamber, the chamber 202c is a chemical vapor deposition (CVD), and the chamber 202d is an atomic layer deposition (ALD) chamber. The degassing chamber is used to remove gaseous and/or liquid substances, such as moisture and oxygen, from the wafer 102 to prevent changes in material characteristics, which may cause deposition failure. It should be noted that the example above is not intended to be limiting, and the techniques disclosed herein are generally applicable to multi-chamber semiconductor processing systems where different chambers have different target temperatures.

In the example shown in FIG. 2, the transfer robot 218 includes one or more rods 220 connected end to end between a motor 222 and a holding member 224 by one or more bearings 226. The motor 222 is configured to vertically, horizontally, and/or rotationally move the holding member 224 along the bearings 226. In one embodiment, the holding member 224 includes one or more blades, and each of the one or more blades includes a pair of laterally spaced fingers typically configured to support a single wafer 102. In one example, the holding member 224 includes five blades. In another embodiment, the holding member 224 includes one or more holding plates. It should be understood that the above embodiments or examples are not intended to be limiting, and the transfer robot 218 may have various forms and designs. It should also be understood that although one transfer robot 218 is shown in FIG. 2, more than one transfer robot 218 can be accommodated in the transfer chamber 216 and operate in an orchestrated and coordinated manner.

The primary control system 248 is electrically coupled with the chambers 202a-202d, the load locks 204, the loading robot 232, and the transfer robot 218. The primary control system 248 is configured to control chambers 202a-202d, the load locks 204, the loading robot 232, and the transfer robot 218. As discussed above, the primary control system 248 is also electrically coupled with the load port 234 and may control a portion of the operations or functions of the load port 234 when the load port is not being troubleshot.

In the example shown in FIG. 2, the load port first aid terminal 114 is disposed in close proximity to the load port 234. The load port first aid control system 112 and the load port first aid terminal 114 are in electrical communication with the load port 234.

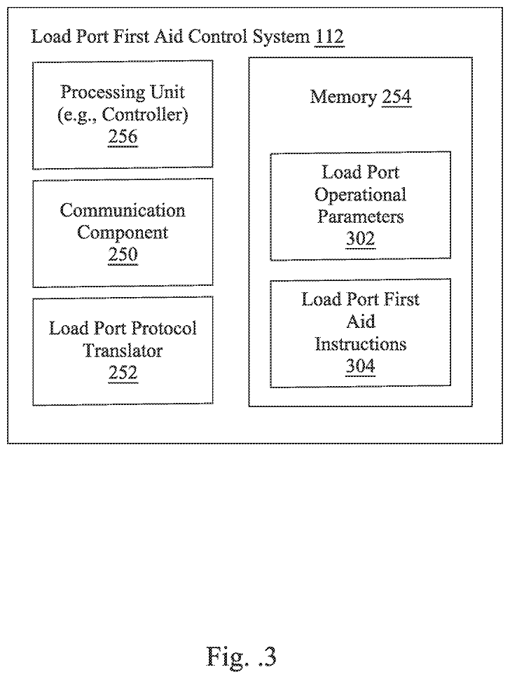

FIG. 3 is a block diagram illustrating an example load port first aid control system 112 in accordance with some embodiments. In the example shown in FIG. 3, the load port first aid control system 112 includes, among other things, a processing unit 256, a memory 254, a communication component 250, and a load port protocol translator 252.

The processing unit 256 is configured to execute codes or instructions stored in the memory 254 to cause the load port first aid control system 112 to perform various functions disclosed herein. In one embodiment, the processing unit 256 is a central processing unit (CPU), a multi-core processor, a distributed processing system, an application specific integrated circuit (ASIC), a controller, and/or a suitable processing unit.

The memory 254 is configured to store the codes or instructions that are executed by the processing unit 256. In addition, the memory 254 also stores the load port operational parameters 302 and the load port first aid instructions 304. The load port operational parameters 302 are collected and stored in the memory 254 when the load port first aid control system 112 controls the load port 234 during the troubleshooting of the load port 234. The load port operational parameters 302 may be transmitted to the primary control system 248 subsequently when the semiconductor processing system 100 recovers from the anomaly. The load port first aid instructions 304 are predetermined instructions that can be performed when a technician troubleshoots the load port 234. For example, the load port first aid instructions 304 may include instructions to close the door of a wafer container 246 shown in FIG. 2. As another example, the load port first aid instructions 304 may include instructions to close the door of the load port 234 shown in FIG. 2. As yet another example, the load port first aid instructions 304 may include instructions to send load port operational parameters 302 to another destination (e.g., a central management platform located in the FAB for further analysis).

In various implementations, the memory 254 may include one or more of a solid-state memory, a magnetic tape, a removable computer diskette, a random-access memory (RAM), a read-only memory (ROM), a rigid magnetic disk, an optical disk, and/or a suitable memory device.

The communication component 250 allows software and data to be transferred between the load port first aid control system 112 and external components, such as the load port 234 and the load port handling mechanism 233 shown in FIG. 1. The communication component 250 can include a modem, a network interface (such as an Ethernet card), a communications port, or the like. Software and data transferred via the communication component 250 are in the form of signals which may be electronic, electromagnetic, optical, or other signals capable of being received by the communication component. These signals are provided to the communication component 250 via a communications path (e.g., the communication path 118 shown in FIG. 1), which can be implemented using wire or cable, fiber optics, a phone line, a cellular phone link, an RF link, or other communications channels.

The load port protocol translator 252 translates signals or instructions among various load port communication protocols. As discussed above, load ports provided by different vendors have different specifications and load port communication protocols. The coexistence of different load port communication protocols in the FAB makes it harder to deploy a load port first aid control system 112 that can be universally relied on in the FAB.

For instance, a first load port 234 may use a first load port communication protocol (e.g., RS-232, which is a standard originally introduced for serial communication transmission of data): a second load port 234 may use a second load port communication protocol (e.g., DIO, sometimes also referred to as “General Purpose Input/Output (GPIO)”); a third load port 234 may use a third load port communication protocol (e.g., SEMI Equipment Communications Standard (SECS), which is a semiconductor equipment interface protocol).

Without the load port protocol translator 252, the load port first aid platform 110 must customize its communication with the load port 234 based on the specific load port communication protocol. In contrast, the load port protocol translator 252 transforms or translates various load port communication protocols to a standard load port communication protocol used in the FAB.

In some embodiments, the standard load port communication protocol is an existing one, such as the RS-232 communication protocol, the DIO or GPIO communication protocol, or the SECS communication protocol. In other embodiments, the standard load port communication protocol is a customized communication protocol defined by the FAB.

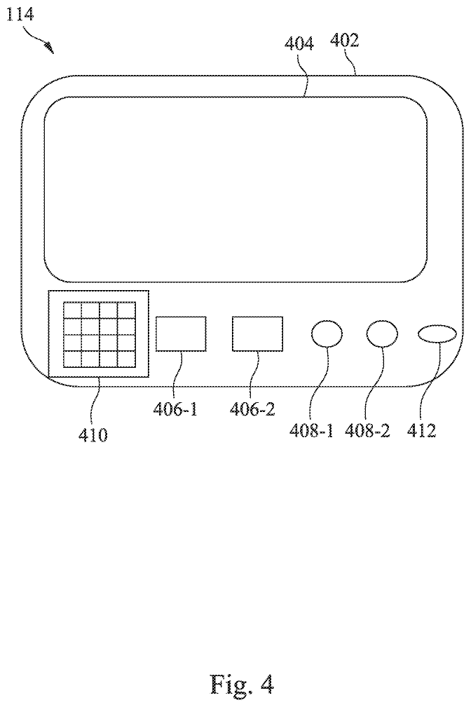

FIG. 4 is a diagram illustrating an example load port first aid terminal 114 in accordance with some embodiments. In the example shown in FIG. 4, the load port first aid terminal 114 includes, among other components, a terminal body 402, a display 404, a first predetermined instruction button 406-1, a second predetermined instruction button 406-2, a first indicator LED 408-1, a second indicator LED 408-2, a keyboard 410, a microphone 412.

The display 404 displays or presents information on the status of the load port 234 shown in FIG. 2. In some embodiments, basic information on the load port 234 (e.g., the make and model of the load port 234, the current software version of the load port 234, etc.) is presented on the display 404. In other embodiments, the last troubleshooting date and summary are presented on the display 404. It should be understood that any suitable types of information can be presented on the display 404. In some embodiments, the display 404 is a touchscreen and serves as an input device as well.

The first predetermined instruction button 406-1 and the second predetermined instruction button 406-2 are used to trigger predetermined first aid instructions stored as the load port first aid instructions 304 shown in FIG. 3. In one embodiment, the first predetermined instruction button 406-1 triggers instructions to close the door of a wafer container 246 shown in FIG. 2, while the second predetermined instruction button 406-2 triggers instructions to close the door of the load port 234 shown in FIG. 2.

The first indicator LED 408-1 indicates the connectivity of the load port first aid terminal 114. When the connectivity of the load port first aid terminal 114 with the load port first aid control system 112 shown in FIG. 1, the load port 234 shown in FIG. 1, and the load port handling mechanism 233 is above the threshold requirements (e.g., the latency is below a predetermined threshold latency), the first indicator LED 408-1 emits, for example, a green light. Otherwise, the first indicator LED 408-1 emits, for example, a red light. A technician inspects and troubleshoots the load port first aid terminal 114 when he sees the red light emitted by the first indicator LED 408-1.

The second indicator LED 408-2 indicates the status of the load port first aid terminal 114. When the status of the load port first aid terminal 114 is normal, the second indicator LED 408-2 emits, for example, a green light. Otherwise, the second indicator LED 408-2 emits, for example, a red light. A technician inspects and troubleshoots the load port first aid terminal 114 when he sees the red light emitted by the second indicator LED 408-2.

The keyboard 410 is an example of input devices that can be employed to input instructions to the load port first aid terminal 114. The microphone 412 is another example of input devices that can be employed to input instructions to the load port first aid terminal 114. The voice instructions received by the microphone 412 can be processed and recognized by the load port first aid terminal 114 or by the load port first aid control system 112 if transmitted to the load port first aid control system 112.

The load port first aid terminal 114 provides a user-friendly interface between a technician and the load port first aid platform 110 shown in FIG. 1, thereby increasing the efficiency and security of performing troubleshooting of the load port 234 shown in FIG. 1.

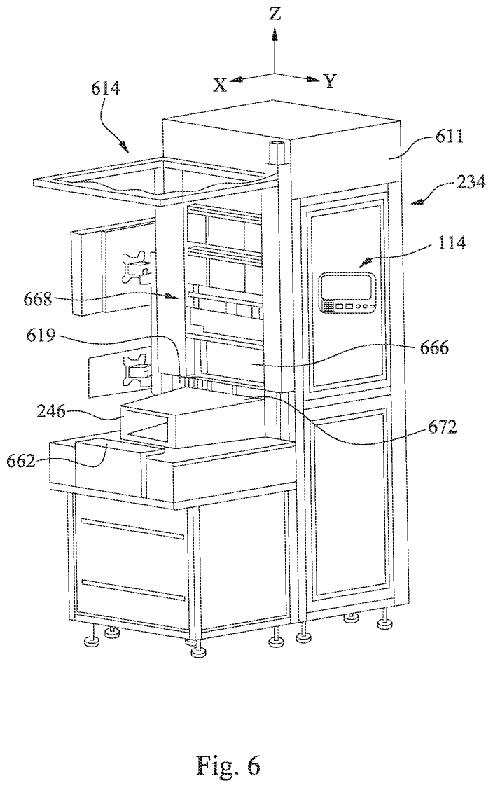

FIG. 6 is a diagram illustrating an example load port 234 in conjunction with an example load port first aid terminal 114 in accordance with some embodiments. As shown in FIG. 6, the load port 234 includes a housing 611, a table 662, a light shutter 614, a door opening/closing mechanism 666, and a door storage 668. The load port 234 may be located on a floor of a FAB for handling wafer containers.

The table 662 may be configured to receive a wafer container 246 from a transport tool, e.g., a vehicle of an OHT that is physically coupled to a ceiling of the FAB and is located higher than the table 662. The wafer container 246 has a door 672 on the back of the wafer container 246, i.e., on the side facing the housing 611.

The door opening/closing mechanism 666 in this example, as one example of the load port handling mechanism 233 shown in FIG. 1, is coupled to the housing 611 and located at the front side of the housing 611, i.e., at the side facing the wafer container 246. The door opening/closing mechanism 666 may be configured to open the door 672 of the wafer container 246, e.g., by a latch key and vacuum pin, and move the door 672 away from the wafer container 246, toward the back of the wafer container 246 along the −X direction as shown in FIG. 6. The door opening/closing mechanism 666 may then hold the door 672 and move it up along the Z direction to the door storage 668.

The door storage 668 in this example is coupled to the housing 611 and located at the front side of the housing 611, i.e., at the side facing the wafer container 246. The door storage 668 may be physically connected to the door opening/closing mechanism 666. The door opening/closing mechanism 666 is movable relative to the door storage 668, along the Z and −Z directions. The door storage 668 in this example includes four door storage units. It can be understood that a door storage space may include one or more door storage units for storing doors 672 of wafer containers 246. For example, after moving the door 672 up to one of the door storage units, the door opening/closing mechanism 666 may rotate the door pin by the latch key to fix the door 672 into the door storage unit. The door 672 is stored in the door storage unit while the wafer container 246 is loaded for wafer processing.

The light shutter 614 in this example is coupled to the housing 611 and located at the front side of the housing 611 and above the table 662. The wafer container 246 is transported by a transport tool, e.g., an OHT, from up of the load port 234 along the −Z direction, through the light shutter 614 and down to the table 662. The light shutter 614 can capture light information of a wafer transport path between the light shutter 614 and the table 662. Because any wafer container is received by the table 662 through the wafer transport path, if there is any object or obstacle located on the wafer transport path, continuing transporting wafer containers may cause a collision. As such, a sensor (not shown), e.g., an E84 sensor, that is electrically connected to the light shutter 614 may determine whether there is an obstacle on the wafer transport path based on the light information captured by the light shutter 614 and send a signal to the OHT, to stop OHT from transporting any more wafer container onto the table 662, until the wafer transport path is clear and has no obstacle. For example, after an E84 sensor connected to the light shutter 614 determines that there is an obstacle between the light shutter 614 and the table 662, the E84 sensor may inform another sensor, e.g., an E87 sensor, connected to the OHT, about the obstacle to stop OHT from transporting wafer containers to the table 662. Then, after the light information reflects that obstacle is gone and the wafer transport path is clear, the E84 sensor may inform the E87 sensor with another signal, to ask the OHT to continue transporting wafer containers to the table 662.

The housing 611 has an input gateway 619 facing the back side of the wafer container 246. The table 662 is movable relative to the housing 611. After the wafer container 246 is unloaded, the door opening/closing mechanism 666 may be configured to retrieve a door from the door storage 668. The retrieved door may be the original door 672 of the wafer container 246 before the wafer container 246 is loaded or may be another door 672 having the same model as the original door 672 to fit the wafer container 246. The door opening/closing mechanism 666 may hold and move down the retrieved door 672 along the −Z direction from the corresponding storage unit and close the retrieved door 672 onto the wafer container 246, e.g., by a latch key and vacuum pin. The OHT may then transport the unloaded wafer container 246 to another load port for further processing of the one or more wafers in the wafer container 246.

In the example shown in FIG. 6, the load port first aid terminal 114 is attached to a lateral surface of the housing 611 of the load port 234. Since the load port first aid terminal 114 is in close proximity to the load port 234, it is convenient and efficient for the technician to operate the load port first aid terminal 114 with the load port 234 and the wafer container 246 in his sight.

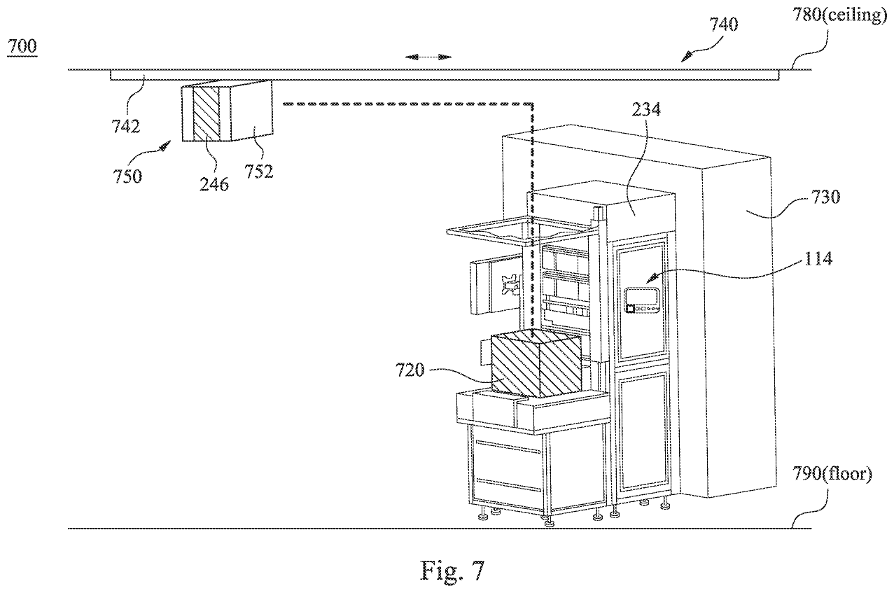

FIG. 7 is a diagram illustrating an environment in which an example load port 234 operates in accordance with some embodiments. In the example shown in FIG. 7, a FAB 700 includes a wafer transport tool 740 and a load port 234, in accordance with some embodiments of the present disclosure. The portion of the FAB 700 shown in FIG. 7 may be a schematic perspective diagram of an automatic material handling system (AMHS). As shown in FIG. 7, the AMHS includes a wafer transport tool 740, e.g., an OHT system, and a load port 234.

In one example, the wafer transport tool 740 includes a network of stationary tracks or rails 742 operable to guide the movement of one or more wheeled OHT vehicles 750 supported and suspended from the rails 742. In some embodiments, the rails 742 are monorails that are mounted to and suspended from the ceiling 780 and/or walls of the FAB. Rails 742 have any suitable cross-sectional configuration as will be appreciated by those in the art so long as the OHT vehicle 750 are appropriately supported from the rail 742 for rolling motion.

An OHT vehicle 750 is operable to transport a wafer container 246 through the FAB 700 for intra-bay or inter-bay movement. The OHT vehicle 750 is configured and structured to hold a wafer container 246 housing a plurality of wafers and transport the wafer container 246 in a generally horizontal or lateral direction from one location to another within the FAB 700.

The OHT vehicle 750 is configured and operable to pick up, raise/lower, hold, articulate, and release a wafer container 246. In one embodiment, the OHT vehicle 750 includes a motor-driven or pneumatic hoisting mechanism 752 generally comprised of gripper assembly including one or more retractable and extendable gripper arms having a gripper on the end thereof configured for locking onto a mating hook or flange on the wafer container 246. The hoisting mechanism 752 is operable to vertically raise and lower the gripper and attached wafer container 246.

As shown in FIG. 7, the OHT vehicle 750 can hold the wafer container 246, transport the wafer container 246 along the rail 742, and release the wafer container 246 onto the table of the load port 234. The load port 234 can automatically open and store the door of the wafer container 246 and load the wafer container 246 for a processing tool 730 to process at least one wafer in the wafer container 246. In this example, the processing tool 730 is coupled to the load port 234. Both the load port 234 and the processing tool 730 are located on the floor 790 of the FAB 700.

In some embodiments, there are multiple processing tools in the FAB 700, and each processing tool is coupled to a corresponding load port 234. In this situation, after the at least one wafer in the wafer container 246 is processed and the wafer container 246 is unloaded by the load port 234, the OHT vehicle 750 can pick up the wafer container 246 from the load port 234 and transport the wafer container 246 to the next load port for additional wafer processing at the processing tool coupled to the next load port 234.

In the example shown in FIG. 7, the load port first aid terminal 114 is attached to a lateral surface of the housing 611 of the load port 234. Since the load port first aid terminal 114 is in close proximity to the load port 234, it is convenient and efficient for the technician to operate the load port first aid terminal 114 with the load port 234 and the wafer container 246 in his sight.

### Example Method for Operating a Load Port First Aid Platform

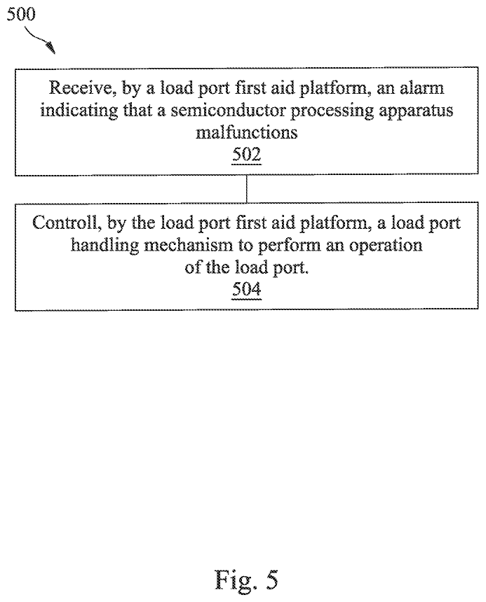

FIG. 5 is a flowchart diagram illustrating an example method 500 for operating a load port first aid platform in accordance with some embodiments. In the example shown in FIG. 5, the method 500 includes operations 502 and 504. Additional operations may be performed. Also, it should be understood that the sequence of the various operations discussed above with reference to FIG. 7 is provided for illustrative purposes, and as such, other embodiments may utilize different sequences. These various sequences of operations are to be included within the scope of embodiments.

At operation 502, an alarm indicating that a semiconductor processing apparatus (e.g., the semiconductor processing apparatus 101 shown in FIG. 1) malfunctions is received by a load port first aid platform (e.g., the load port first aid platform 110 shown in FIG. 1).

At operation 504, the load port first aid platform controls a load port handling mechanism (e.g., the load port handling mechanism 233 shown in FIG. 1) to perform an operation of the load port. In one embodiment, the operation is closing a door of a wafer container containing a wafer to be loaded to the semiconductor processing apparatus. In another embodiment, the operation is closing a door of the load port.

Additional operations may be included. For example, a notification message may be sent to a technician through, for example, the load port first aid terminal 114 shown in FIG. 4.

A Load Port First Aid Platform Shared by More than One Semiconductor Processing System

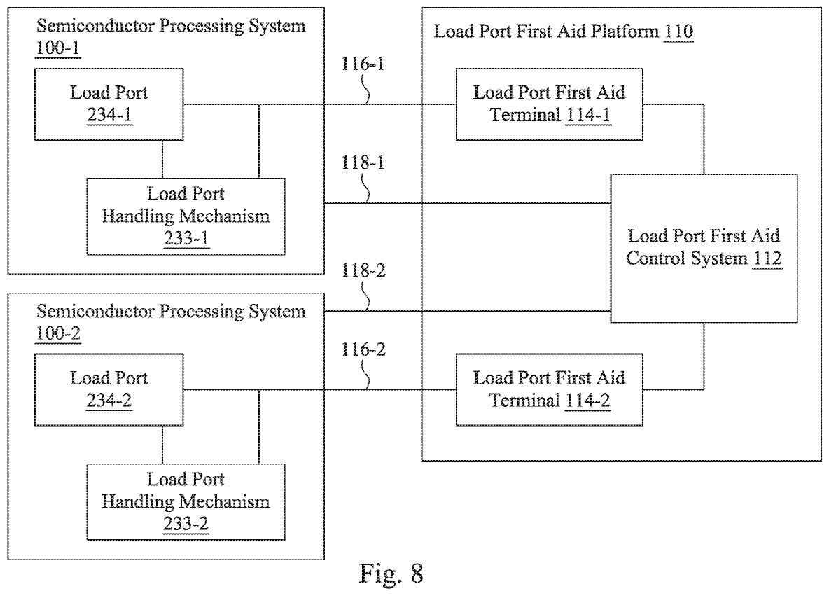

FIG. 8 is a block diagram illustrating an example load port first aid platform 110 in conjunction with a first semiconductor processing system 100-1 and a second semiconductor processing system 100-2 in accordance with some embodiments. Components that are identical to or similar to the counterpart components shown in FIG. 1 are not described in detail.

In the example shown in FIG. 8, the load port first aid platform 110 includes a first load port first aid terminal 114-1 and a second load port first aid terminal 114-2. The first load port first aid terminal 114-1 is in electrical communication with the load port 234-1 and the load port handling mechanism 233-1 of the first semiconductor processing system 100-1. The second load port first aid terminal 114-2 is in electrical communication with the load port 234-2 and the load port handling mechanism 233-2 of the second semiconductor processing system 100-2.

In other words, the load port first aid platform 110 is shared by two semiconductor processing systems, namely the first semiconductor processing system 100-1 and the second semiconductor processing system 100-2. As such, the cost of providing the load port first aid platform 110 disclosed herein can be reduced.

On the other hand, the load port 234-1 and the load port 234-2 may have different load port communication protocols, which necessitate the load port protocol translation performed by the load port protocol translator 252 shown in FIG. 3.

### SUMMARY

In accordance with some aspects of the disclosure, a system is provided. The system includes: a semiconductor processing system comprising: a semiconductor processing apparatus configured to perform at least one semiconductor fabrication process; and a load port attached to the semiconductor processing apparatus and configured to load a wafer contained in a wafer container to the semiconductor processing apparatus; and a load port first aid platform in electrical communication with the load port, wherein the load port first aid platform controls the load port when the semiconductor processing apparatus malfunctions.

In accordance with some aspects of the disclosure, a method is provided. The method includes: receiving, by a load port first aid platform, an alarm indicating that a semiconductor processing apparatus malfunctions; and controlling, by the load port first aid platform, a load port handling mechanism to perform an operation of the load port.

In accordance with some aspects of the disclosure, a load port first aid platform is provided. The load port first aid platform is in electrical communication with a semiconductor processing apparatus and a load port. The load port first aid platform includes: a load port first aid control system configured to control the load port when the semiconductor processing apparatus malfunctions; and a load port first aid terminal configured to provide a user interface between a technician and the load port first aid control system.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system comprising:
a semiconductor processing system comprising:
a semiconductor processing apparatus configured to perform at least one semiconductor fabrication process; and
a load port attached to the semiconductor processing apparatus and configured to load a wafer contained in a wafer container to the semiconductor processing apparatus; and
a load port first aid platform in electrical communication with the load port, wherein the load port first aid platform controls the load port when the semiconductor processing apparatus malfunctions.

2. The system of claim 1, wherein the semiconductor processing system further comprise:
a primary control system configured to control the semiconductor processing apparatus and the load port when the semiconductor processing apparatus functions.

3. The system of claim 2, wherein the semiconductor processing system further comprises:
a load port handling mechanism configured to perform an operation of the load port when the semiconductor processing apparatus malfunctions.

4. The system of claim 3, wherein the operation is closing a door of the wafer container.

5. The system of claim 3, wherein the operation is closing a door of the load port.

6. The system of claim 3, wherein the load port handling mechanism comprises at least one electrical solenoid valve.

7. The system of claim 3, wherein the load port handling mechanism is integrated into the load port.

8. The system of claim 3, wherein the load port handling mechanism is controlled by the load port first aid platform when the semiconductor processing apparatus malfunctions.

9. The system of claim 1, wherein the load port first aid platform comprises:
a load port first aid control system configured to control the load port when the semiconductor processing apparatus malfunctions; and
a load port first aid terminal configured to provide a user interface between a technician and the load port first aid control system.

10. The system of claim 9, wherein the load port first aid control system comprises:
a load port protocol translator configured to translate a first load port communication protocol to a second load port communication protocol.

11. The system of claim 10, wherein the first load port communication protocol is one of the:
a RS-232 communication protocol;
a General Purpose Input/Output (GIPO) communication protocol; and
a SEMI Equipment Communications Standard (SECS) communication protocol.

12. The system of claim 9, wherein the load port first aid terminal comprises:
a first predetermined instruction button configured to trigger a first predetermined first aid instruction; and
a second predetermined instruction button configured to trigger a second predetermined first aid instruction.

13. The system of claim 12, wherein the first predetermined first aid instruction is to close a door of the wafer container, and the second predetermined first aid instruction is to close a door of the load port.

14. A method comprising:
receiving, by a load port first aid platform, an alarm indicating that a semiconductor processing apparatus malfunctions; and
controlling, by the load port first aid platform, a load port handling mechanism to perform an operation of the load port.

15. The method of claim 14, further comprising:
sending a notification message to a technician.

16. The method of claim 14, wherein the operation is closing a door of a wafer container containing a wafer to be loaded to the semiconductor processing apparatus.

17. The method of claim 14, wherein the operation is closing a door of the load port.

18. A load port first aid platform in electrical communication with a semiconductor processing apparatus and a load port, the load port first aid platform comprising:
a load port first aid control system configured to control the load port when the semiconductor processing apparatus malfunctions; and
a load port first aid terminal configured to provide a user interface between a technician and the load port first aid control system.

19. The load port first aid platform of claim 18, wherein the load port first aid control system is configured to troubleshoot the load port.

20. The load port first aid platform of claim 18, wherein the load port first aid control system is configured to translate a first load port communication protocol to a second load port communication protocol.
